(19) United States
(12) Patent Application Publication
(10) Pub. No.: US 2009/0007951 A1
(43) Pub. Date: Jan. 8, 2009

(54) QUANTUM INJECTION SYSTEM

(76) Inventors: Eliade Stefanescu, Bucharest (RO); Lucien Eugene Cornescu, Bucharest 2 (RO)

Correspondence Address: GRIFFIN & SZIPL, PC, SUITE PH-1, 2300 NINTH STREET, SOUTH, ARLINGTON, VA, 22204, US

(21) Appl. No.: 11/773,862

(22) Filed: Jul. 5, 2007

(51) Int. Cl. H01L 35/34; H01L 35/30

(52) U.S. Cl. 136/201; 136/205

(57) ABSTRACT

A system is disclosed comprising a package of active Fabry-Perot transmitters and an electric charge accumulator for converting a part of coherent electromagnetic power in electric power at the proper voltage of this accumulator. An active Fabry-Perot transmitter is a semiconductor device comprising a packet of p-i-n diodes with double quantum dots on the two sides of the i-layer, separated by potential barriers from the conduction regions. The semiconductor structure is placed in a Fabry-Perot cavity with total transmission. While a resonant coherent electromagnetic beam is crossing the Fabry-Perot cavity, a small part from the electromagnetic energy is captured by resonant electron excitations through the i-layer, injecting an electron current in the device.

The present application is related to co-pending U.S. patent application Ser. No. ______, filed on Jul. 5, 2007, and titled “Longitudinal Quantum Heat Converter,” and to co-pending U.S. patent application Ser. No. ______, filed on Jul. 5, 2007, and titled “Transversal Quantum Heat Converter.” The entire disclosures of the above patent applications are hereby incorporated by reference.

### FIELD OF INVENTION

The present invention generally concerns a package of active transmitters and an electric charge accumulator for converting a part of a coherent electromagnetic power in electric power at the proper voltage of the accumulator.

### BACKGROUND OF THE INVENTION

In the co-pending applications Ser. Nos. “B-16581” & “B-16582” entitled “Longitudinal quantum heat converter” and respectively “Transversal quantum heat converter”, which are both incorporated herein by reference, disclose a heat flow propagating through a quantum heat converter being transformed into super radiant power propagating in the same direction or in a perpendicular direction to the heat flow direction. The operation of these devices is essentially based on the injection of an electron current, but at a much lower power than the generated optical power that comes by heat absorption. In order to optimize the production of energy according to the aforecited co-pending applications, it is important to set free from the need of an external current supply.

### SUMMARY OF THE INVENTION

The goal of the present invention is to optimize quantum heat converters as disclosed in the above mentioned co-pending applications and for that purpose concerns a semiconductor device for converting a part of an optical power generated by a quantum heat converter and crossing the semiconductor device in electric power. On this basis, the necessary electric current to a quantum heat converter can be obtained on the account of the power produced just by this converter.

According to a first aspect, the invention concerns an active transmitter comprising a resonant cavity formed by two mirrors and at least one p-i-n structure with quantum dots on each side of the i-layer defining a quantum dot region, and potential barriers to separate this quantum dot region from the conduction p and n regions, wherein the p-i-n structure is placed in the resonant cavity.

According to another aspect, the invention concerns a method for transforming a part of a coherent electromagnetic beam into electric current by super radiant transitions in an active transmitter.

According to another aspect, the invention concerns a quantum injection system for converting a part of a coherent electromagnetic flow into electric power, including several active transmitters of claim 1, optically and electrically connected in series and an accumulator connected in parallel with the series circuit of these transmitters.

According to another aspect, the invention concerns a quantum injection system for converting a part of a coherent electromagnetic flow into electric power, including several active transmitters, optically and electrically connected in series, and an accumulator connected in parallel with the series circuit of these transmitters.

### BRIEF DESCRIPTION OF THE DRAWINGS

Other features and advantages of the invention will appear upon reading the following description which refers to the annexed drawings in which:

FIG. 1 represents the active Fabry-Perot transmitter of the present invention;

FIG. 2 represents a symbol of a an active Fabry-Perot resonator;

FIG. 3 represents the quantum injection system of the present invention;

FIG. 4 represents a symbol of a quantum injection system;

### DETAILED DESCRIPTION OF THE INVENTION

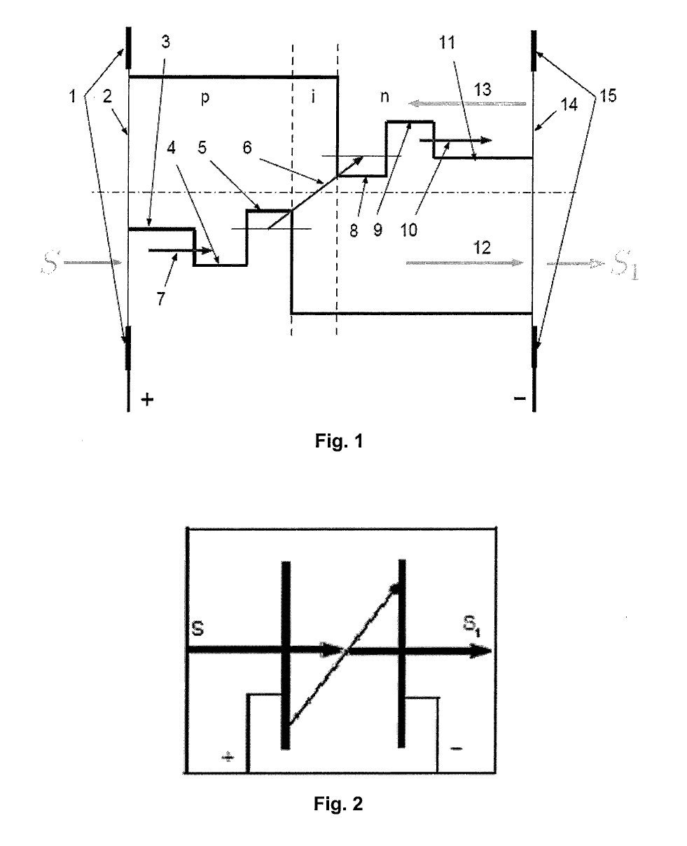

The present invention will now be detailed only by way of non limiting examples in relation with FIGS. 1 to 4.

FIG. 1 represents an active Fabry-Perot transmitter for the partial conversion of a coherent electromagnetic power in electric power. According to a first aspect of the invention, the transmitter comprises a semiconductor device comprising a p-i-n diode 3-11 with double array of quantum dots 5 and 8 on both sides of the i-layer, separated by potential barriers 4 and 9 from the conduction regions 7 and 11. The semiconductor structure is placed in a Fabry-Perot cavity 2 and 14 with total transmission. While a resonant coherent electromagnetic beam is crossing the cavity, a small part from the electromagnetic energy is captured by resonant electron excitations 6 through the i-layer, injecting an electron current in the device.

Thus, a coherent electromagnetic beam S with an amplitude ε, being incident on the partially transmitting mirror 2 of the perfectly tuned Fabry-Perot resonator with the two mirrors 2 and 14 with the same transmission coefficient T| that enclose the semiconductor structure 3-11, is coupled to this structure. If this resonator were empty, the transmitted beam S1 would be of the same amplitude ε₁=ε, while the two inner waves 12 and 13 would have the amplitudes

$${ɛ}_{12} = \frac{1}{𝒯} ɛ \vert$$

and respectively

$${ɛ}_{13} = - \frac{ℛ}{𝒯} ɛ$$

Due to the resonant transitions 6, the two inner waves 12 and 13 are partially absorbed, while a tunneling diffusion current is generated through the two potential barriers 4 and 9. The two electron tunneling flows 7 an 10 depend on the two potential barriers 4 and respectively 9 and on the potential wells 5 and respectively 8 that determine the two energy levels of the transition 6 in comparison with the margins of the valence band of the p-region and respectively of the conduction band of the n-region. The intermediate i-region determines the dipole moment that determines the amount of energy that will be able to transfer electrons from the well 5 to the well 8. The generated current is collected at the ring electrodes 1 and 15.

FIG. 2 represents a symbol of an active Fabry-Perot resonator of FIG. 1 with the optical terminals S for the incoming beam and S1 for the outgoing beam, and the electrical terminals +, −.

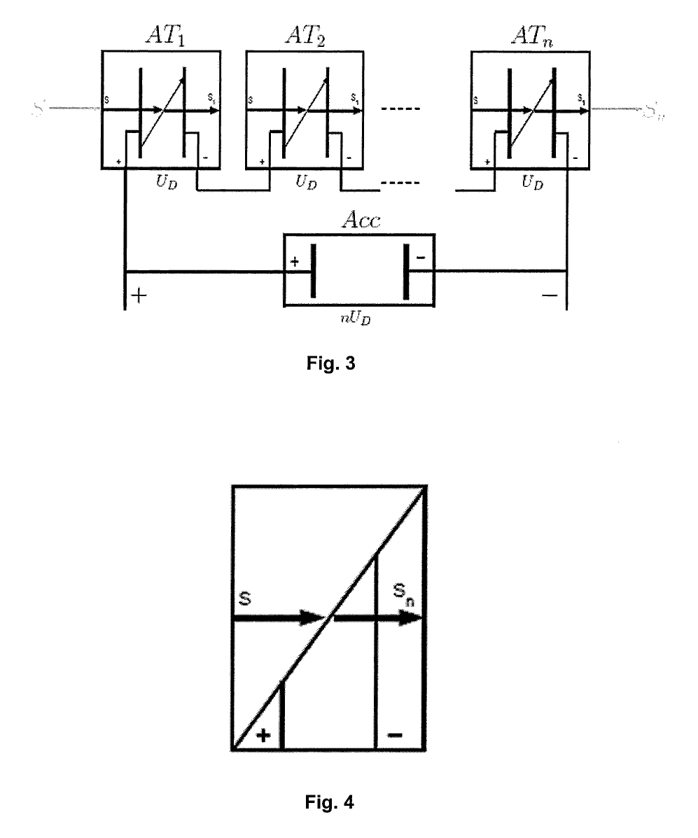

FIG. 3 represents a quantum injection system according to another aspect of the present invention. Such quantum injection system comprises several active transmitters such the ones above described in relation with FIG. 1 and an electric charge accumulator for transforming part of a coherent electromagnetic power into electric power at the proper voltage of this accumulator. More specifically, the system advantageously consists in a package of active Fabry-Perot transmitters AT₁-AT_{N} as a series circuit in parallel with a charge accumulator Acc. In the operation regime, while the total voltage provided by the series circuit of active Fabry-Perot transmitters is higher than the accumulator voltage, this accumulator is charging. When the device is disconnected, the accumulator is discharging through the series circuit of active Fabry-Perot transmitters till reaches a lower voltage than the openness voltage of this circuit.

This quantum injection system is based on the fact that an active Fabry-Perot transmitter is in fact a p-i-n photo-diode with semitransparent electrodes that means that under the incoming electromagnetic energy flow S every transmitter provides the voltage U_{D} of an open diode. The voltage U_{D} corresponds to the current I_{D} that is the same for all these diodes, that means that the total voltage generated by the circuit is nU_{D}, while the outgoing electromagnetic energy flow Sₙ=S−nI_{D}U_{D}−(the dissipated energy flow).

The voltage nU_{D} provided by the n active Fabry-Perot transmitters AT₁, AT₂, . . . , ATₙ, matching the proper voltage of the accumulator Acc, under this voltage the accumulator is charged. A necessary condition for this operation is that the electron current I_{D} be provided in every diode by optical excitation. When the attenuation of the optical flow by absorption in the active Fabry-Perot transmitters is taken into account, to obtain the same excitation current I_{D} one has to cancel this attenuation by increasing the quantum transition dipole momentum.

FIG. 4 represents a symbol of a quantum injection system of FIG. 3 with the optical terminals S of the incoming beam and Sₙ of the outgoing beam, and the electric terminals + and −.

Having described the invention with regard to certain specific embodiments, it is to be understood that these embodiments are not meant as limitations of the invention. Indeed, various modifications, adaptations and/or combination between embodiments may become apparent to those skilled in the art without departing from the scope of the annexed claims.

1. An active transmitter comprising:
(a) a resonant cavity formed by two mirrors, and at least one p-i-n structure with quantum dots on each side of the i-layer defining a quantum dot region; and
b) potential barriers to separate the quantum dot region from the conduction p and n regions, wherein the p-i-n structure is placed in the resonant cavity.

2. The active transmitter of claim 1, wherein the two mirrors form a perfectly tuned Fabry-Perot resonator.

3. A method for transforming a part of a coherent electromagnetic beam into electric current by super radiant transitions in an active transmitter according to claim 1.

4. A quantum injection system for converting a part of a coherent electromagnetic flow into electric power, including:
(a) several active transmitters of claim 1, optically and electrically connected in series in a circuit; and
(b) an accumulator connected in parallel with the series circuit of the several active transmitters.

5. The quantum injection system of claim 4, wherein an opening voltage of the series circuit of active transmitters matches a proper voltage of the accumulator.

6. The quantum injection system of claim 5, wherein an increase of transition dipole moments cancels a decrease of electromagnetic flow due to resonant absorption in the active transmitters.

7. A quantum injection system for converting a part of a coherent electromagnetic flow into electric power, including:
(a) several active transmitters of claim 2, optically and electrically connected in series in a circuit; and
(b) an accumulator connected in parallel with the series circuit of the several active transmitters.

8. A method for converting a part of a coherent electromagnetic flow into electric power in a quantum injection system of claim 4, comprising the steps of:
(a) providing the quantum injection system of claim 4 with coherent electromagnetic flow; and
(b) converting a part of the electromagnetic flow into electric power by super radiant transitions in active transmitters.
